(19) United States
(12) Patent Application Publication
(10) Pub. No.: US 2025/0329686 A1
(43) Pub. Date: Oct. 23, 2025

(54) SEMICONDUCTOR PACKAGE

(71) Applicant: Samsung Electronics Co., Ltd., Suwon-si (KR)

(72) Inventor: Youngchae JEON, Suwon-si (KR)

(21) Appl. No.: 18/898,766

(22) Filed: Sep. 27, 2024

(30) Foreign Application Priority Data
Apr. 17, 2024 (KR) 10-2024-0051728

(51) Int. Cl. H01L 23/00; H01L 23/13; H01L 23/528; H01L 23/538; H01L 25/065

(52) U.S. Cl. CPC H01L 24/73; H01L 23/13; H01L 23/5283; H01L 24/16; H01L 24/48; H01L 25/0657; H01L 23/538; H01L 24/17; H01L 2224/16145; H01L 2224/16227; H01L 2224/17181; H01L 2224/48101; H01L 2224/48227; H01L 2224/73257; H01L 2225/06513; H01L 2225/06572

(57) ABSTRACT

According to the present invention, a semiconductor package is provided. A semiconductor package may include a package substrate, and a first semiconductor chip disposed on the package substrate, wherein the first semiconductor chip may include a semiconductor substrate including a first surface and a second surface opposite to the first surface, a circuit pattern region disposed on the first surface of the semiconductor substrate and including a plurality of circuit patterns, a signal wiring layer disposed on the circuit pattern region and electrically connected to the plurality of circuit patterns, and a power wiring layer disposed on the second surface of the semiconductor substrate and electrically connected to the plurality of circuit patterns through a plurality of through vias extending through the semiconductor substrate, and the package substrate may include a signal transmission pattern electrically connected to the signal wiring layer of the first semiconductor chip, and a power transmission pattern electrically connected to the power wiring layer of the first semiconductor chip.

### CROSS-REFERENCE TO RELATED APPLICATION

This application claims priority to Korean Patent Application No. 10-2024-0051728, filed in the Korean Intellectual Property Office on Apr. 17, 2024, the entire contents of which are hereby incorporated by reference.

### BACKGROUND

### Field

The present invention and disclosure relate to a semiconductor package.

### Description of Related Art

An active region, in which an integrated circuit (or majority of integrated circuits) is formed, may be typically located on a front side of a semiconductor substrate. Additionally, power wiring and signal wiring may be connected to the front side of the semiconductor substrate to supply power and transmit signals from the package to the active region of the semiconductor substrate. However, semiconductor devices are becoming ultra-highly integrated in response to demands for miniaturization and high capacity, and as a result, congestion may occur in supplying power and transmitting signals to the front side of the semiconductor substrate.

### SUMMARY

In order to solve one or more problems (e.g., the problems described above and/or other problems not explicitly described herein), the present disclosure provides a semiconductor package.

According to an embodiment of the present disclosure, a semiconductor package may include a package substrate, and a first semiconductor chip disposed on the package substrate, wherein the first semiconductor chip may include a semiconductor substrate including a first surface and a second surface opposite to the first surface, a circuit pattern region disposed on the first surface of the semiconductor substrate and including a plurality of circuit patterns, a signal wiring layer disposed on the circuit pattern region and electrically connected to the plurality of circuit patterns, and a power wiring layer disposed on the second surface of the semiconductor substrate and electrically connected to the plurality of circuit patterns through a plurality of through vias extending through the semiconductor substrate, and the package substrate may include a signal transmission pattern electrically connected to the signal wiring layer of the first semiconductor chip, and a power transmission pattern electrically connected to the power wiring layer of the first semiconductor chip.

According to an embodiment of the present disclosure, a semiconductor package may include a package substrate, and a chip stack disposed on the package substrate and including a plurality of semiconductor chips including a first semiconductor chip and a second semiconductor chip stacked on each other, wherein each of the first semiconductor chip and the second semiconductor chip may include a semiconductor substrate including a first surface and a second surface opposite to the first surface, a circuit pattern region disposed on the first surface of the semiconductor substrate and including a plurality of circuit patterns, a signal wiring layer disposed on the circuit pattern region and electrically connected to the plurality of circuit patterns, and a power wiring layer disposed on the second surface of the semiconductor substrate and electrically connected to the plurality of circuit patterns through a plurality of through vias extending through the semiconductor substrate, and the package substrate may include a signal transmission pattern electrically connected to the signal wiring layer included in at least one of the first semiconductor chip or the second semiconductor chip, and a power transmission pattern electrically connected to the power wiring layer included in at least one of the first semiconductor chip or the second semiconductor chip.

According to an embodiment of the present disclosure, a semiconductor package may include a package substrate including a signal transmission pattern and a power transmission pattern, and a semiconductor chip disposed on the package substrate, wherein the semiconductor chip may include a semiconductor substrate including a first surface and a second surface opposite to the first surface, a circuit pattern region disposed on the first surface of the semiconductor substrate and including at least one circuit pattern, a signal wiring portion including a signal wiring layer disposed on the circuit pattern region and electrically connected to the circuit pattern, and a power wiring portion including a power wiring layer disposed on the second surface of the semiconductor substrate and electrically connected to the circuit pattern region through a through via extending through the semiconductor substrate, the signal wiring layer of the semiconductor chip is electrically connected to the signal transmission pattern of the package substrate, and the power wiring layer of the semiconductor chip is electrically connected to the power transmission pattern of the package substrate.

Other specific details of the present disclosure and invention are included in the detailed description and the drawings.

According to some aspects of the present disclosure, because the signal transmission and the power supply are carried out on both sides of the semiconductor chip, sufficient wiring space may be secured on both sides of the semiconductor chip, and as a result, it is possible to reduce the size of the semiconductor chip, contributing significantly to the miniaturization and high integration of the semiconductor chip. In addition, because the sufficient number of power pads for providing various types of voltages (ground, VDD, VSS, etc.) may be provided in the semiconductor package, it is possible to improve power integrity (PI). In addition, because the surface where the signal wirings are formed is positioned on an opposite side to a surface of the semiconductor chip where the power wirings are formed, congestion in transmitting signals may be mitigated, thereby improving signal integrity (SI).

According to some examples of the present disclosure, because the semiconductor chip is received (accommodated) in a cavity formed in the package substrate, the length of the bonding wire can be reduced, compared to when the semiconductor chip is disposed on a flat surface of the package substrate. Accordingly, it is possible to prevent electrical performance from deteriorating due to the inductance component of the bonding wire, and as a result, improve signal integrity (SI) and power integrity (PI) of the semiconductor package.

According to some examples of the present disclosure, by mounting a plurality of semiconductor chips in a plurality of cavities formed on both sides of the package substrate, it is possible to implement a high-capacity semiconductor package while minimizing the package size.

According to some examples of the present disclosure, by mounting a plurality of semiconductor chips in a stepped cavity formed on a side of the package substrate, it is possible to implement a high-capacity semiconductor package while minimizing the package size.

The advantages of the present disclosure are not limited to those described above, and other advantages not described herein may be clearly understood by those of ordinary skill in the art (referred to as “ordinary technician”) from the description of the embodiments and claims.

### BRIEF DESCRIPTION OF THE DRAWINGS

The above and other objects, features and advantages of the present disclosure will be described with reference to the accompanying drawings described below, where similar reference numerals indicate similar elements, but not limited thereto, in which:

FIG. 1 is a cross-sectional view illustrating an example of a semiconductor chip.

FIG. 2 is a cross-sectional view illustrating an example of the semiconductor chip.

FIG. 3 illustrates an example of a semiconductor package.

FIG. 4 is a cross-sectional view illustrating an example of the semiconductor package according to another aspect of the present disclosure.

FIG. 5 is a cross-sectional view illustrating an example of the package substrate including a cavity C formed therein.

FIG. 6 is a cross-sectional view illustrating an example of the semiconductor package.

FIG. 7 is a cross-sectional view illustrating an example of the semiconductor package.

FIGS. 8 and 9 are diagrams illustrating how to determine a first distance d1 in the semiconductor package.

FIG. 10 is a cross-sectional view illustrating an example of the package substrate including cavities C1 and C2 formed on both sides thereof.

FIG. 11 is a cross-sectional view illustrating an example of the semiconductor package according to an aspect of the present disclosure.

FIG. 12 is a cross-sectional view illustrating an example of the semiconductor package according to another aspect of the present disclosure.

FIG. 13 is a cross-sectional view illustrating an example of a chip stack according to an aspect of the present disclosure.

FIG. 14 is a cross-sectional view illustrating an example of the chip stack according to another aspect of the present disclosure.

FIG. 15 is a cross-sectional view illustrating an example of the package substrate including a stepped cavity formed therein.

FIG. 16 is a cross-sectional view illustrating an example of the semiconductor package including the chip stack according to an aspect of the present disclosure.

FIG. 17 is a cross-sectional view illustrating an example of the semiconductor package including the chip stack according to another aspect of the present disclosure.

### DETAILED DESCRIPTION

In drawings and discussion thereon below, items common may retain the same or similar reference designation, unless the context clearly indicates otherwise. Accordingly, the present disclosure may repeat reference numerals and/or letters in the various examples and drawings, such that like reference numerals between figures indicate like items, elements, steps and so on. This repetition is for the purpose of simplicity and clarity and does not in itself dictate a relationship between the various embodiments and/or configurations discussed.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

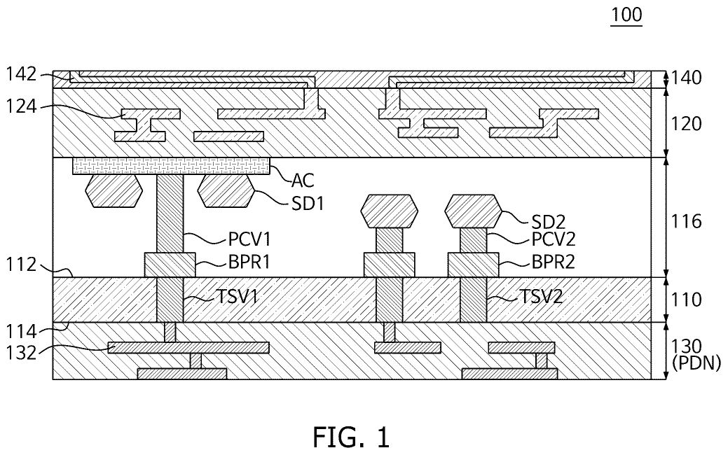

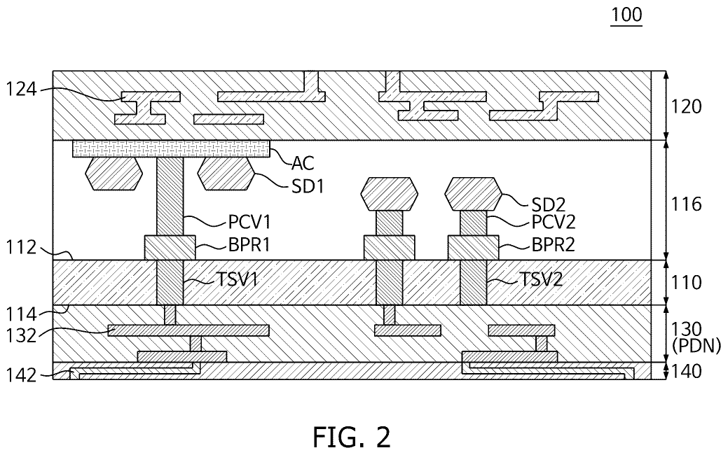

FIG. 1 is a cross-sectional view illustrating an example of a semiconductor chip 100, and FIG. 2 is a cross-sectional view illustrating another example of the semiconductor chip 100. Referring to FIGS. 1 and 2, the semiconductor chips 100 each may include a semiconductor substrate 110, an element region (also described as a circuit pattern region) 116, a signal wiring portion 120, and a power wiring portion 130. The descriptions in conjunction with FIG. 1 or 2 may be applicable to the semiconductor chips in both figures, unless specified otherwise by the context and unless the descriptions explicitly conflict with what is depicted in each drawing.

The semiconductor substrate 110 may have a first surface 112 and a second surface 114 opposite to the first surface 112. The element region 116 including a semiconductor element (e.g., a transistor, a capacitor, a diode, a resistor, etc. and conductive patterns connecting therebetween) for performing a function of an integrated circuit may be disposed on the first surface 112 of the semiconductor substrate 110. For example, the element region 116 may include a semiconductor element (also described as a circuit pattern) including source/drain (source and/or drain) patterns SD1 and SD2, etc. (e.g., a transistor including the source/drain patterns SD1 and SD2).

In some embodiments, the semiconductor element may be formed in the semiconductor substrate 110. In some embodiments, a part of the semiconductor element may be formed in the semiconductor substrate 110, and another part of the semiconductor element may be formed in the element region 116. In some embodiment, a plurality of semiconductor elements may be formed in both the semiconductor substrate 110 and in the element region 116. As described above, the region where semiconductor elements are formed may undergo various modifications, and this variation may be similarly implemented in other semiconductor chips described later, unless the context indicates otherwise.

The signal wiring portion 120 may be disposed on the element region 116. The signal wiring portion 120 may include a signal wiring layer 124. Though not shown in the drawings, the signal wiring layer 124 may be electrically connected to the semiconductor element included in the element region 116.

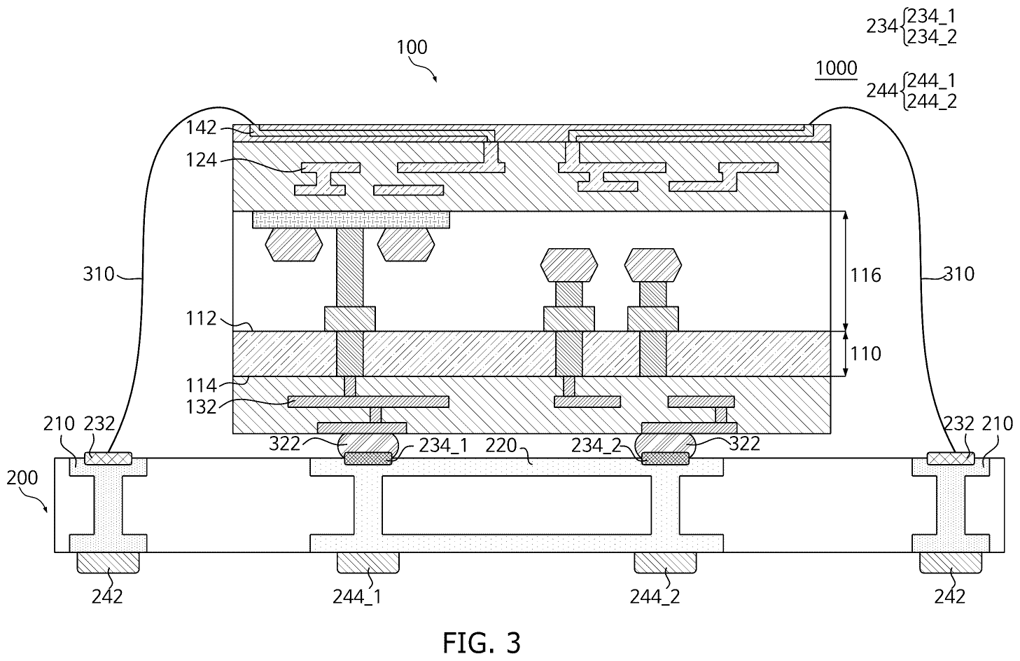

The signal wiring portion 120 may be electrically connected to signal transmission layers 210 (which may form one or more signal transmission patterns) of a package substrate 200 (illustrated in FIG. 3). As a result, through the signal wiring layer 124, electrical signal may be transmitted from the signal transmission layers 210 of the package substrate 200 to the element region 116 (e.g., the semiconductor element included in the element region 116).

The power wiring portion 130 may be disposed on the second surface 114 of the semiconductor substrate 110. The power wiring portion 130 may form a back-side power delivery network (BSPDN) including a power wiring layer 132 electrically connected to the semiconductor element (e.g., the source/drain patterns SD1 and SD2 of the semiconductor element) included in the element region 116 through buried power rails BPR1 and BPR2.

The term “buried” may refer to structures, patterns, and/or layers that are formed at least partially below a surface of another structure, pattern, and/or layer. For example, a structure, pattern, and/or layer may be considered “buried” when it is partially embedded in or surrounded by another structure, pattern, and/or layer.

The power wiring layer 132 may be electrically connected to the semiconductor element included in the element region 116 by through vias TSV1 and TSV2 extending through the semiconductor substrate 110. For example, the power wiring layer 132 may be electrically connected to the source/drain pattern SD1 of the semiconductor element through the through via TSV1 extending through the semiconductor substrate 110, the buried power rail BPR1 electrically connected to the through via TSV1, a power contact via PCV1, and an active contact AC. As another example, the power wiring layer 132 may be electrically connected to the source/drain pattern SD2 of the semiconductor element through the through via TSV2 extending through the semiconductor substrate 110, the buried power rail BPR2 electrically connected to the through via TSV2, and a power contact via PCV2. The buried power rails BPR1 and BPR2 may be configured to supply power such as VDD and VSS to the source/drain patterns SD1 and SD2 through the power contact vias PCV1 and PCV2 and/or the active contact AC.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

The power rails BPR1 and BPR2 may be formed to be buried in element region 116. For example, the power rails BPR1 and BPR2 may be formed in recesses of the element region 116. Exposed portions of the power rails BPR1 and BPR2 may be in contact with the through vias TSV1 and TSV2. Burying the power rails BPR1 and BPR2 under the semiconductor element as described above may reduce the height of a standard cell (not illustrated in the drawings), which includes the semiconductor element. In addition, the power wiring portion 130 may be disposed on the under the element region 116 and the semiconductor substrate 110, and power may be supplied to the power rails BPR1 and BPR2 through the through vias TSV1 and TSV2. The power wiring portion 130 may be disposed on the second surface 114 (also described as rear surface or backside) of the semiconductor substrate 110. As a result, BSPDN may be implemented in the power wiring portion 130. The backside 114 is located opposite to a surface or side of the element region 116 on which the signal wiring layer 124 is disposed. This separate arrangement of the power wiring layer 132 and the signal wiring layer 124 may be helpful to ensure various design advantages of the wiring configuration of the semiconductor chip. In addition, the buried power rails BPR1 and BPR2 may have a shape (e.g., a shape of a landing pad) to facilitate efficiently supplying power to the semiconductor elements by utilizing the through vias TSV1 and TSV2.

The power wiring portion 130 may be electrically connected to a power transmission layer (also described transmission pattern) of the package substrate. As a result, power may be transmitted through the power wiring layer 132 from the power transmission layer of the package substrate to the element region 116 (e.g., semiconductor element included in the element region 116, for example, the source/drain patterns SD1 and SD2).

The semiconductor chips 100 each may further include a redistribution portion 140 including a redistribution layer 142. For example, as illustrated in FIG. 1, the redistribution portion 140 including the redistribution layer 142 may be disposed on the signal wiring layer 124. As another example, as illustrated in FIG. 2, the redistribution portion 140 including the redistribution layer 142 may be disposed on the power wiring layer 132.

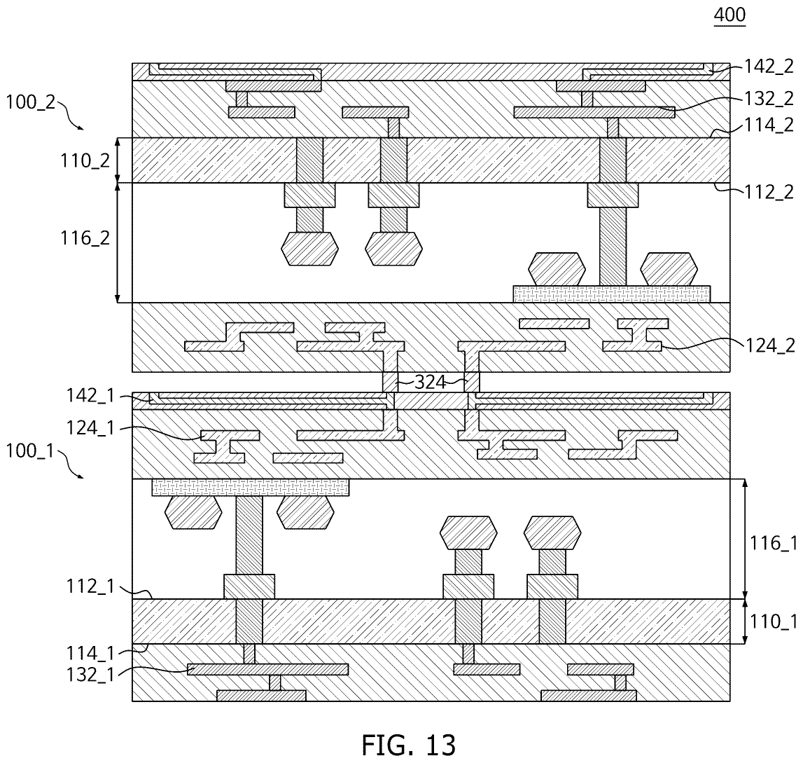

As yet another example, a first redistribution layer may be disposed on the signal wiring layer 124, and a second redistribution layer may be disposed on the power wiring layer 132. For example, a chip stack 400 (shown in FIG. 13) may include a first redistribution layer 142_1 disposed on the signal wiring layer 124_1, and a second redistribution layer 142_2 disposed on the power wiring layer 132_2.

A portion of each of the signal wiring layer 124, the power wiring layer 132 and the redistribution layer 142 may be externally exposed, and the exposed portions each may serve as a pad for wiring connection between an external configuration (e.g., the package substrate 200 in FIG. 3) and one of the signal wiring layer 124, the power wiring layer 132 and the redistribution layer 142. For example, in the semiconductor chip 100 illustrated in FIG. 1, an exposed portion the redistribution layer 142 may serve as a pad for connecting the signal wiring layer 124 to an external configuration, and an exposed portion of the power wiring layer 132 may serve as a pad for connecting the through via TSV1 to the external configuration. For example, in the semiconductor chip 100 illustrated in FIG. 2, an exposed portion the redistribution layer 142 may serve as a pad for connecting the power wiring layer 132 to a package substrate, and an exposed portion of the signal wiring layer 124 may serve as a pad for connecting the semiconductor elements to the package substrate.

Additionally or alternatively, at least part of the signal wiring layer 124, the power wiring layer 132, or the redistribution layer 142 may further include a separate pad for wiring connections with external configurations.

For example, though not shown in the drawings, the semiconductor chip 100 may include an additional pad layer, and the pad layer may include a plurality of conductive patterns. For example, conductive metal patterns may be disposed on the exposed portions of the signal wiring layer 124, the power wiring layer 132 and the redistribution layer 142. The plurality of conductive patterns each may serve as a pad for wiring connection between an external configuration and one of the signal wiring layer 124, the power wiring layer 132 and the redistribution layer 142.

FIG. 3 illustrates an example of a semiconductor package 1000. The semiconductor package 1000 may include a package substrate 200 including a wiring layer and the semiconductor chip 100 (described in FIG. 1) disposed on the package substrate 200.

The package substrate 200 may be a substrate on which the semiconductor chip 100 is mounted. For example, the package substrate 200 may be a printed circuit board (PCB), but the invention is not limited thereto. The package substrate 200 may include a wiring layer (or a plurality of wiring layers), and the wiring layer may include signal transmission layers 210 and power transmission layers 220. The signal transmission layers 210 may form one or more signal transmission patterns. The power transmission layers 220 may form one or more power transmission patterns.

The package substrate 200 may include the signal transmission layer 210 and the power transmission layer 220 may be arranged in an insulating material such as glass reinforced epoxy resin. The signal transmission layer 210 of the package substrate 200 may be electrically connected to the signal wiring layer 124 of the semiconductor chip 100 disposed on the package substrate 200. In addition, the signal transmission layer 210 of the package substrate 200 may be connected to a first connection terminal 242, and may receive an electrical signal from an external configuration (e.g., a CPU (central processing unit)) through the first connection terminal 242. The electrical signal received from the external configuration through the first connection terminal 242 may be transmitted to the signal wiring layer 124 of the semiconductor chip 100 through the signal transmission layer 210 of the package substrate 200.

The power transmission layer 220 of the package substrate 200 may be electrically connected to the power wiring layer 132 of the semiconductor chip 100 disposed on the package substrate 200. In addition, the power transmission layer 220 of the package substrate 200 may be connected to a second connection terminal 244 and may receive power from an external configuration through the second connection terminal 244. For example, the power supplied from the external configuration (e.g., power source) through the second connection terminal 244 may be transmitted to the power wiring layer 132 of the semiconductor chip 100 through the power transmission layer 220 of the package substrate 200.

A contact pad 234 may be formed on a chip placement region of a first surface of the package substrate 200, which is a region on which the semiconductor chip 100 is disposed, and a bonding pad 232 may be formed on a chip peripheral region of the first surface of the package substrate 200, which is a region that surrounds the chip placement region. The contact pad 234 and the bonding pad 232 may be connected to the signal transmission layer 210 and the power transmission layer 220, respectively. For example, as illustrated in FIG. 3, the bonding pad 232 may be connected to the signal transmission layer 210 of the package substrate 200, and the contact pad 234 may be connected to the power transmission layer 220.

The semiconductor chip 100 may be disposed on the first surface (e.g., upper surface) of the package substrate 200. For example, the semiconductor chip 100 may include the semiconductor substrate 110 including the first surface 112 (also described as front surface or upper surface) and the second surface 114 (e.g., rear surface or backside) opposite to the first surface 112, the element region 116 and the signal wiring layer 124 disposed on the first surface 112 of the semiconductor substrate 110, the redistribution layer 142 disposed on the signal wiring layer 124, and the power wiring layer 132 disposed on the second surface 114 of the semiconductor substrate 110. The signal wiring layer 124 may transmit the electrical signal from the signal transmission layer 210 of the package substrate 200 to the element region 116 (e.g., the semiconductor element included in the element region 116). In addition, the power wiring layer 132 may form a back-side power delivery network (BSPDN) that supplies, through buried power rails, the power transmitted from the power transmission layer 220 of the package substrate 200 to the semiconductor element (e.g., the source/drain patterns of semiconductor element) included in the element region 116. As illustrated, the semiconductor chip 100 may be disposed on the first surface of the package substrate 200 such that the second surface 114 of the semiconductor substrate 110 faces the first surface of the package substrate 200.

The semiconductor package 1000 may further include a bonding wire 310 and a bump 322 to connect the semiconductor chip 100 and the semiconductor substrate 110. For example, the bonding wire 310 may connect the redistribution layer 142 of the semiconductor chip 100 to the bonding pad 232, and the bump 322 may connect the power wiring layer 132 of the semiconductor chip 100 and the contact pad 234 to each other. Accordingly, the electrical signal received from the external configuration through the first connection terminal 242 may be transmitted to the redistribution layer 142 disposed on the signal wiring layer 124 of the semiconductor chip 100 through the signal transmission layer 210 and the bonding wire 310. Additionally, the power supplied from the external configuration through the second connection terminal 244 may be transmitted to the power wiring layer 132 of the semiconductor chip 100 through the power transmission layer 220 and the contact pad 234.

FIG. 3 illustrates that a plurality of contact pads 234_1 and 234_2 are all connected to the same power transmission layer 220, but the invention is not limited thereto. For example, each of the contact pads 234_1 and 234_2 may be connected to a corresponding one of two power transmission layers which are electrically separated from each other. Different types of power may be connected to the semiconductor chip 100 through the contact pads 234_1 and 234_2. For example, each of VDD and VSS may be electrically connected to one of the contact pads 234_1 and 234_2, which are electrically separated from each other. The bumps 322 may be directly connected to the contact pads 234_1 and 234_2.

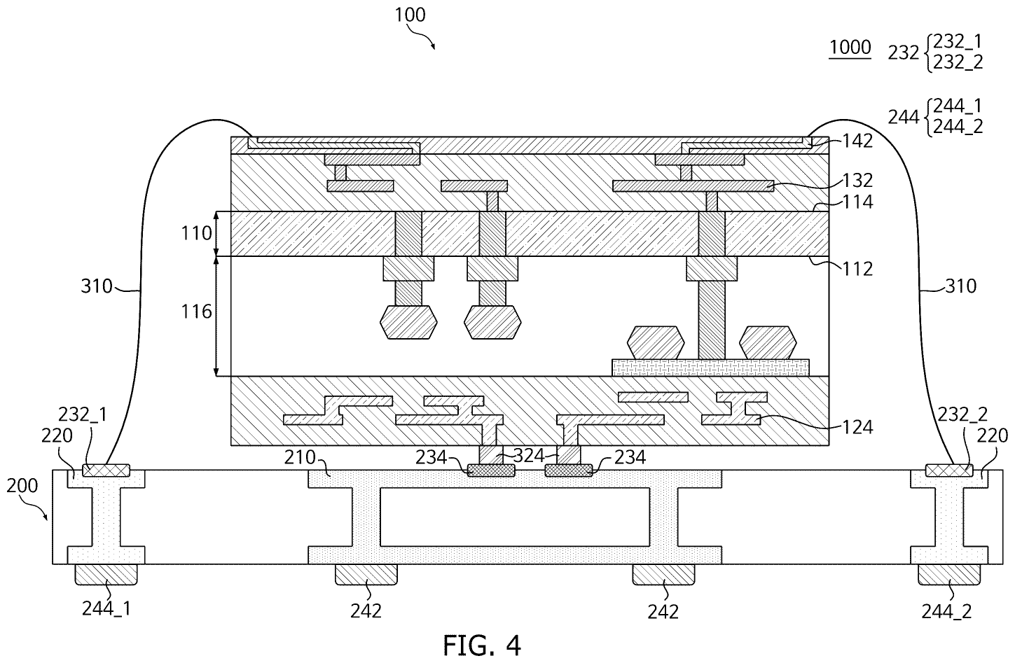

FIG. 4 is a cross-sectional view illustrating an example of a semiconductor package 1000 according to another aspect of the present disclosure. In the following description of FIG. 4, the same elements as or similar elements to those of the embodiment illustrated in FIG. 3 will not be described again or will be described only briefly and differences from the embodiment illustrated in FIG. 3 will be mainly described.

The contact pad 234 may be formed on the chip placement region of the first surface of the package substrate 200, which is the region on which the semiconductor chip 100 (shown in FIG. 2) is disposed, and the bonding pad 232 may be formed on the chip peripheral region of the first surface of the package substrate 200, which is the region that surrounds the chip placement region. The contact pad 234 and the bonding pad 232 may be connected to the signal transmission layer 210 and the power transmission layer 220, respectively. For example, as illustrated in FIG. 4, the bonding pad 232 may be connected to the power transmission layer 220 of the package substrate 200, and the contact pad 234 may be connected to the signal transmission layer 210.

The semiconductor chip 100 may be disposed on the first surface (e.g., upper surface) of the package substrate 200. For example, the semiconductor chip 100 may include the semiconductor substrate 110 including the first surface 112 (e.g., front surface or lower surface) and the second surface 114 (e.g., rear surface or backside) opposite to the first surface 112, the element region 116 and the signal wiring layer 124 disposed on the first surface 112 of the semiconductor substrate 110, the power wiring layer 132 disposed on the second surface 114 of the semiconductor substrate 110, and the redistribution layer 142 disposed on the power wiring layer 132. The signal wiring layer 124 may transmit the electrical signal from the signal transmission layer 210 of the package substrate 200 to the element region 116 (e.g., the semiconductor element included in the element region 116). In addition, at least part or entire of the power wiring layer 132 may constitute a back-side power delivery network (BSPDN). The BSPDN may be used to supply, through buried power rails, the power transmitted from the power transmission layer 220 of the package substrate 200 to the semiconductor element (e.g., the source/drain patterns of semiconductor element) included in the element region 116. As illustrated, the semiconductor chip 100 may be disposed on the first surface of the package substrate 200 in the form of a flip chip (i.e., the semiconductor chip 100 in FIG. 2. is turned over)_such that the first surface 112 of the semiconductor substrate 110 faces the first surface of the package substrate 200.

The semiconductor package 1000 may further include a bonding wire 310 and a bump 324 to connect the semiconductor chip 100 and the semiconductor substrate 110. For example, the semiconductor package 1000 may further include the bonding wire 310 that connects the redistribution layer 142 of the semiconductor chip 100 and the bonding pad 232, and the bump 324 that connects the signal wiring layer 124 of the semiconductor chip 100 and the contact pad 234. Accordingly, the electrical signal received from the external configuration through the first connection terminal 242 may be transmitted to the signal wiring layer 124 of the semiconductor chip 100 through the signal transmission layer 210 and the contact pad 234. In addition, the power supplied from the external configuration through the second connection terminal 244 may be transmitted to the redistribution layer 142 disposed on the power wiring layer 132 of the semiconductor chip 100 through the power transmission layer 220 and the bonding wire 310.

As described above, because the signal transmission and the power supply are carried out on both sides of the semiconductor chip 100, sufficient wiring space may be secured on both sides of the semiconductor chip 100, and as a result, it is possible to reduce the size of the semiconductor chip 100, contributing significantly to the miniaturization and high integration of the semiconductor chip 100 . . . . In addition, because the sufficient number of power pads for providing various types of voltages (ground, VDD, VSS, etc.) may be provided in the semiconductor package 1000, it is possible to improve power integrity (PI). In addition, because the surface where the signal wirings are formed is positioned on an opposite side to a surface of the semiconductor chip 100 where the power wirings are formed, congestion in transmitting signals may be mitigated, thereby improving signal integrity (SI).

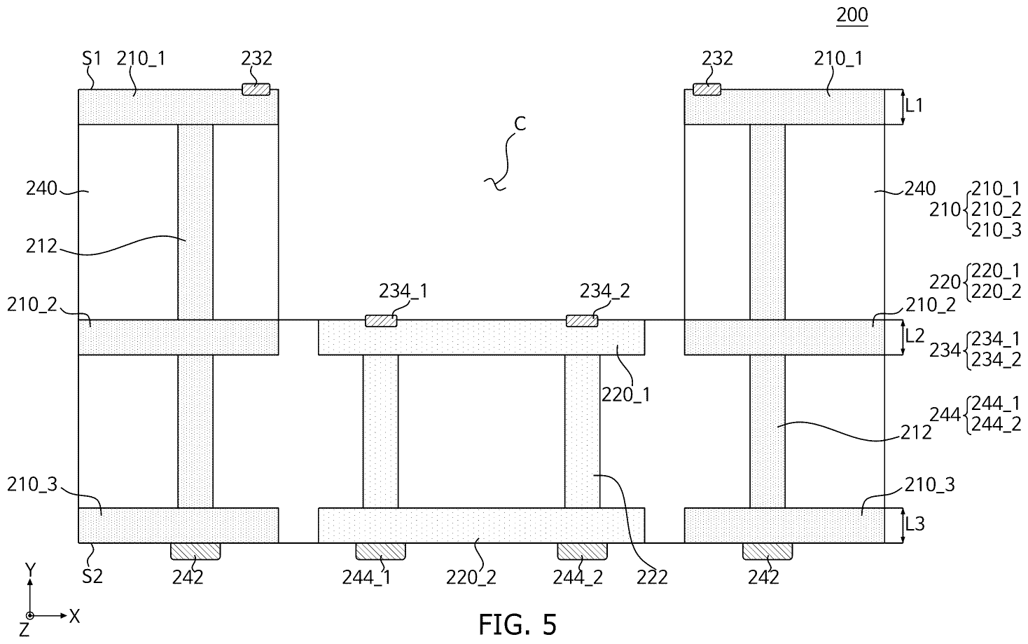

FIG. 5 is a cross-sectional view illustrating an example of a package substrate 200 including a cavity C formed therein. Referring to FIG. 5, the package substrate 200 may include a first surface S1 and a second surface S2 opposite to the first surface S1. The cavity C may be formed on the first surface S1 of the package substrate 200. For example, the cavity C may be formed in the package substrate 200 by removing, e.g., etching away a portion of the package substrate 200 from the first surface S1 toward the second surface S2.

The package substrate 200 may include a plurality of wiring layers L1, L2, and L3 stacked in a vertical direction (direction Y) perpendicular to the first and second surfaces of the package substrate 200 and an insulating layer 240 disposed between the plurality of wiring layers L1, L2, and L3. For example, as illustrated in FIG. 5, the package substrate 200 may include a first wiring layer L1 (210-1), a second wiring layer L2 (210_2, 220_1), and a third wiring layer L3 (210_3, 220_2) sequentially formed in the vertical direction from the first surface S1 to the second surface S2, and the insulating layer 240 (e.g., a dielectric layer) may be disposed between the wiring layers.

The plurality of wiring layers L1, L2, and L3 may include a plurality of wiring patterns. Signal transmission patterns 210 and power transmission patterns 220 may be parts of the plurality of wiring layers L1, L2, and L3 of the package substrate 200. For example, as illustrated in FIG. 5, a first signal transmission pattern 210_1 may be a part of the first wiring layer L1, a second signal transmission pattern 210_2 and a first power transmission layer 220_1 may be parts of the second wiring layer L2, and a third signal transmission layer 210_3 and a second power transmission layer 220_2 may be parts of the third wiring layer L3. The signal transmission layers 210 (210_1, 210_2, and 210_3) disposed on different layers may be connected to each other through first vias 212, and the power transmission layers 220 (220_1 and 220_2) disposed on different layers may be connected to each other through second vias 222.

The signal transmission layers 210 (e.g., the third signal transmission layer 210_3) of the package substrate 200 may be connected to the first connection terminal 242, and may receive an electrical signal from an external configuration through the first connection terminal 242. In addition, the power transmission layer 220 (e.g., the second power transmission layer 220_2) of the package substrate 200 may be connected to the second connection terminal 244 and may receive power from an external configuration through the second connection terminal 244 (244_1, 244_2).

The contact pad 234 (234_1, 234_2) may be formed on a bottom surface of the cavity C, and the first bonding pad 232 may be formed on a peripheral region of the cavity C of the first surface S1 of the package substrate 200. The first bonding pad 232 and the second bonding pad 234 may be connected to the signal transmission layer 210 and the power transmission layer 220, respectively. For example, as illustrated in FIG. 5, the first bonding pad 232 may be connected to the first signal transmission layer 210_1 of the package substrate 200, and the contact pad 234 may be connected to the first power transmission layer 220_1. According to another aspect, the signal transmission layer 210 and the power transmission layer 220 of the package substrate 200 illustrated in FIG. 5 may be arranged such that the first bonding pad 232 may be connected to the power transmission layer 220 of the package substrate 200, and the contact pad 234 may be connected to the signal transmission layer 210.

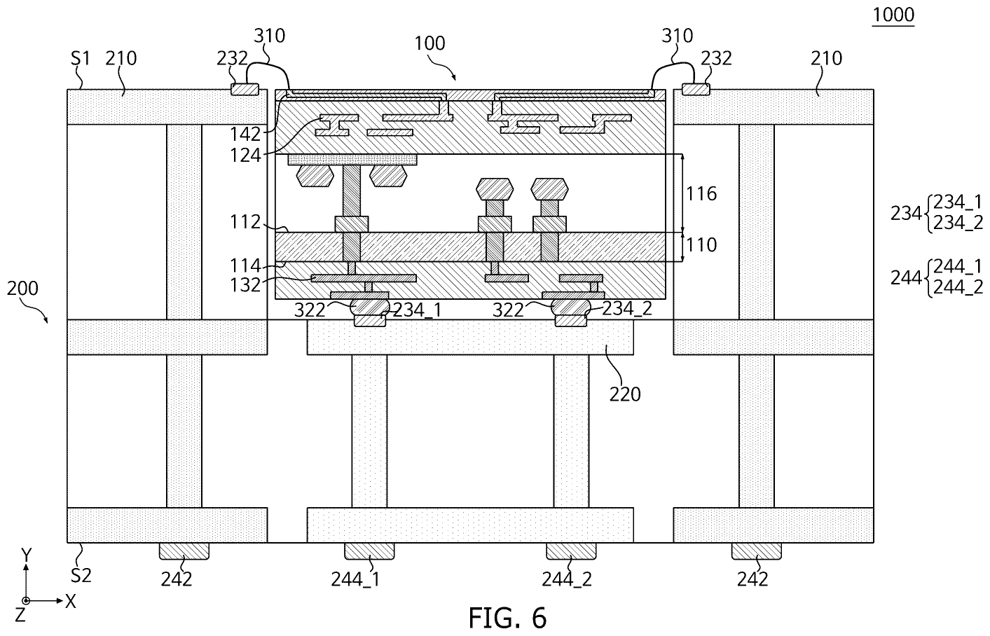

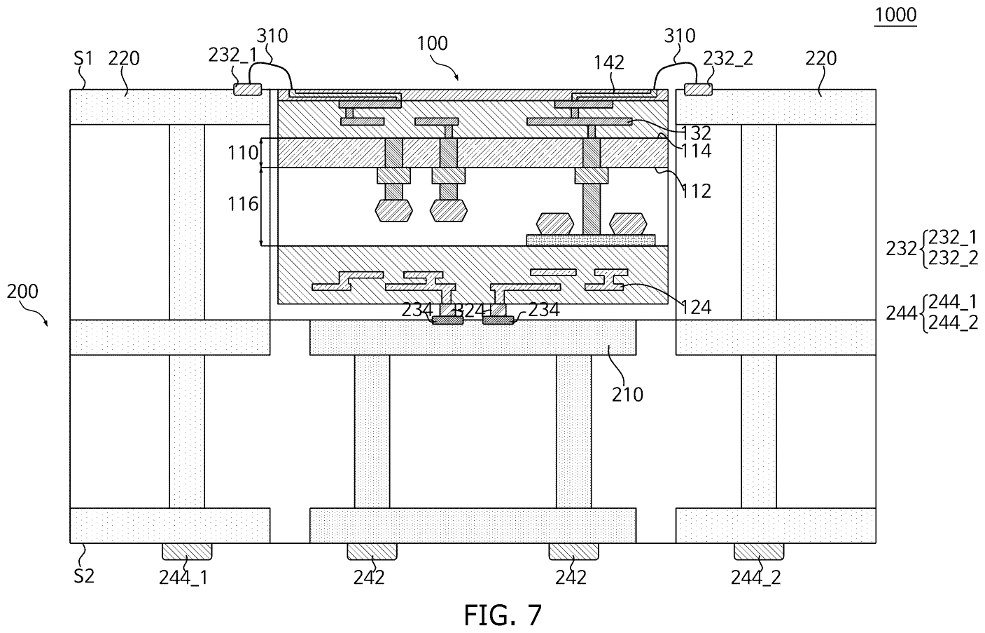

FIG. 6 is a cross-sectional view illustrating an example of the semiconductor package 1000, and FIG. 7 is a cross-sectional view illustrating another example of the semiconductor package 1000. The descriptions in conjunction with FIG. 6 or 7 may be applicable to the semiconductor packages in both figures, unless specified otherwise by the context and unless the descriptions explicitly conflict with what is depicted in each drawing.

Each semiconductor packages 1000 may include the package substrate 200 including a cavity formed therein and the semiconductor chip 100 disposed on the package substrate 200. At least a portion of the semiconductor chip 100 may be received (accommodated) in the cavity formed in the package substrate 200.

Referring to FIG. 6, the semiconductor chip 100 may include the semiconductor substrate 110 including the first surface 112 (e.g., front surface or upper surface) and the second surface 114 (e.g., rear surface or backside) opposite to the first surface 112, the element region 116 and the signal wiring layer 124 disposed on the first surface 112 of the semiconductor substrate 110, the redistribution layer 142 disposed on the signal wiring layer 124, and the power wiring layer 132 disposed on the second surface 114 of the semiconductor substrate 110. The semiconductor chip 100 may be disposed on the bottom surface of the cavity such that the second surface 114 of the semiconductor substrate 110 faces the bottom surface of the cavity, as illustrated in FIG. 6.

Referring to FIG. 7, the semiconductor chip 100 may include the semiconductor substrate 110 including the first surface 112 (front surface) and the second surface 114 (e.g., rear surface) opposite to the first surface 112, the element region 116 and the signal wiring layer 124 disposed on the first surface 112 of the semiconductor substrate 110, the power wiring layer 132 disposed on the second surface 114 of the semiconductor substrate 110, and the redistribution layer 142 disposed on the power wiring layer 132. The semiconductor chip 100 may be disposed on the bottom surface of the cavity in the form of a flip chip such that the first surface 112 of the semiconductor substrate 110 faces the bottom surface of the cavity, as illustrated in FIG. 7.

The semiconductor package 1000 may further include the bonding wire 310 and the bumps 322 and 324 to connect the semiconductor chip 100 and the semiconductor substrate 110. For example, as illustrated in FIGS. 6 and 7, the bonding wire 310 may connect the bonding pad 232 formed on the peripheral region of the cavity and the redistribution layer 142 of the semiconductor chip 100, and the bumps 322 and 324 may connect the contact pad 234 formed on the bottom surface of the cavity and the power wiring layer 132 or the signal wiring layer 124 of the semiconductor chip 100.

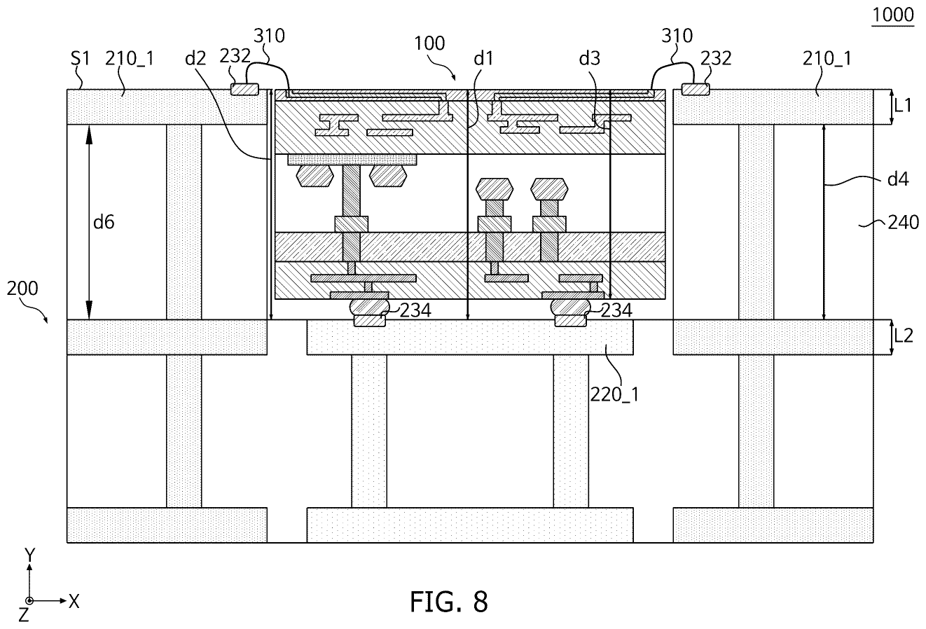

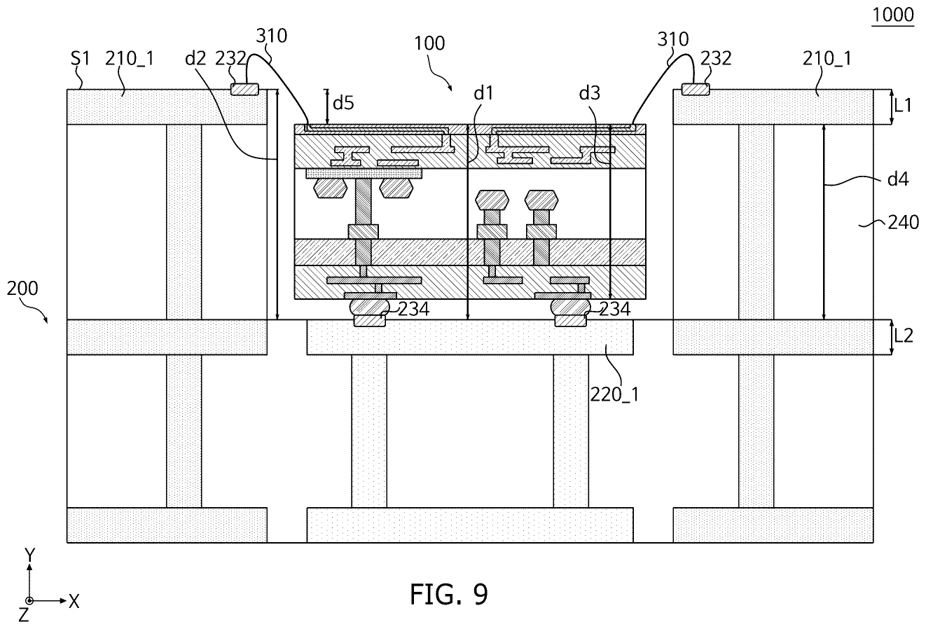

FIGS. 8 and 9 are diagrams illustrating how to determine a first distance d1 in the semiconductor package 1000. The descriptions in conjunction with FIG. 8 or 9 may be applicable to the semiconductor packages in both figures, unless specified otherwise by the context and unless the descriptions explicitly conflict with what is depicted in each drawings.

The semiconductor package 1000 including the semiconductor chip 100 received in the cavity formed in the package substrate 200 may be designed so as to minimize the length of the bonding wire 310 connecting the bonding pad 232 and the semiconductor chip 100. For example, as illustrated in FIG. 8. The first distance d1 is a vertical distance from the bottom surface of the cavity to the upper surface (or the topmost surface) of the semiconductor chip 100. The first distance d1 may be substantially equal to a depth d2 of the cavity. For example, the bonding pad 232 disposed on the peripheral region of the cavity of the first surface of the package substrate 200 and the pad of the redistribution layer 142 positioned on the upper surface of the semiconductor chip 100 are at substantially the same height, thereby minimizing the length of the bonding wire 310 connecting between the bonding pad 232 and the pad of the redistribution layer 142.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

In order to implement the semiconductor package 1000 such that the first distance d1 from the bottom surface of the cavity to the upper surface (or topmost surface) of the semiconductor chip 100 is substantially equal to the depth d2 of the cavity, the insulating layer 240 of the package substrate 200 may be configured to have a predetermined thickness.

For example, if a second distance d6 is equal to a thickness d3 of the semiconductor chip 100, the first distance d1 may be set to be substantially equal to the depth d2 of the cavity. The second distance d6 may be the distance between the wiring layer directly connected to the bonding pad 232 and the wiring layer directly connected to the contact pad 234. The second distance d6 may be the distance between the first wiring layer L1 and the second wiring layer L2. The second distance d6 may be the distance between the first signal transmission layer 210_1 and the first power transmission layer 220_1 in FIG. 8.

For example, if the distance between the wiring layer (e.g., the first wiring layer L1 including the first signal transmission layer 210_1 in FIG. 8) directly connected to the bonding pad 232 disposed on the peripheral region of the cavity and the wiring layer (e.g., the second wiring layer L2 including the first power transmission layer 220_1 in FIG. 8) directly connected to the contact pad 234 disposed on the bottom surface of the cavity is equal to the thickness d3 of the semiconductor chip 100, the distance d1 from the bottom surface of the cavity to the upper surface of the semiconductor chip 100 (to the top of the semiconductor chip 100) may be set to be approximately equal to the depth d2 of the cavity.

To accomplish the relationship previously described, a thickness d4 of the insulating layer 240 disposed between the wiring layer directly connected to the bonding pad 232 disposed on the peripheral region of the cavity and the wiring layer directly connected to the contact pad 234 disposed on the bottom surface of the cavity may be designed to be substantially equal to the thickness d3 of the semiconductor chip 100.

The distances and thicknesses described in conjunction with FIGS. 8 and 9 are dimensions measured in the vertical direction (direction Y).

As illustrated in FIG. 9, the first distance d1 from the bottom surface of the cavity to the upper surface of the semiconductor chip 100 (or, to the top of the semiconductor chip 100) may not be equal to the depth d2 of the cavity. Because the semiconductor chip 100 is received in the cavity formed in the package substrate 200, the length of the bonding wire 310 may still be designed to decrease compared to when the semiconductor chip 100 (shown in FIG. 3) is disposed on the first surface of the package substrate 200. For example, a difference d5 between the depth d2 of the cavity and the first distance d1 from the bottom surface of the cavity to the upper surface of the semiconductor chip 100 (or, to the top of the semiconductor chip 100) may be designed to be less than the first distance d1 from the bottom surface of the cavity to the upper surface of the semiconductor chip 100 (or, to the top of the semiconductor chip 100).

As described above, because the semiconductor chip 100 is received in the cavity formed in the package substrate 200, the length of the bonding wire 310 can decrease compared to when the semiconductor chip 100 (shown in FIG. 3) is disposed on the first surface of the package substrate 200. Accordingly, it is possible to prevent electrical performance from deteriorating due to the inductance component of the bonding wire 310, and as a result, improve signal integrity (SI) and power integrity (PI) of the semiconductor package 1000.

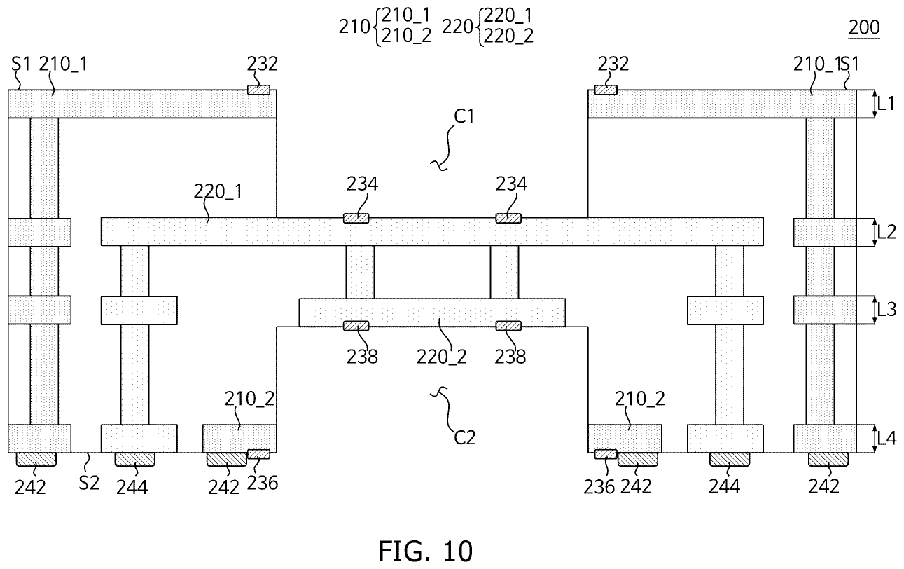

FIG. 10 is a cross-sectional view illustrating an example of the package substrate 200 including cavities C1 and C2 formed on both sides thereof. A plurality of cavities C1 and C2 may be formed on both sides of the package substrate 200. For example, as illustrated, a first cavity C1 may be formed on the first surface S1 of the package substrate 200 and a second cavity C2 may be formed on the second surface S2 of the package substrate 200.

The contact pads 234 and 238 may be formed on the bottom surfaces of each of the cavities C1 and C2. For example, the first contact pad 234 may be formed on the bottom surface of the first cavity C1 formed on the first surface S1, and the second contact pad 238 may be formed on the bottom surface of the second cavity C2 formed on the second surface S2. In addition, the bonding pads 232 and 236 may be formed on the peripheral regions of the cavities C1 and C2 of the first and second surfaces S1 and S2 of the package substrate 200. For example, the first bonding pad 232 may be formed on the peripheral region of the first cavity C1 of the first surface S1 of the package substrate 200, and the second bonding pad 236 may be formed on the peripheral region of the second cavity C2 of the second surface S2 of the package substrate 200.

The bonding pads 232 and 236 may be connected to one of the signal transmission layer 210 or the power transmission layer 220, and the contact pads 234 and 238 may be connected to the signal transmission layer 210 or the power transmission layer 220 that is not connected to the bonding pads 232 or 236.

For example, as illustrated in FIG. 10, the first bonding pad 232 and the second bonding pad 236 may be connected to the signal transmission layer 210, and the first contact pad 234 and the second contact pad 238 may be connected to the power transmission layer 220.

As another example, the first bonding pad 232 and the second bonding pad 236 may be connected to the power transmission layer 220, and the first contact pad 234 and the second contact pad 238 may be connected to the signal transmission layer 210.

In the drawings, it is illustrated that the first contact pad 234 and the second contact pad 238 are connected to different wiring layers (e.g., the second wiring layer L2 and the third wiring layer L3 in FIG. 10) of the package substrate 200, but the invention is not limited thereto. The first contact pad 234 formed on the bottom surface of the first cavity C1 and the second contact pad 238 formed on the bottom surface of the second cavity C2 may be connected to the same wiring layer of the package substrate 200.

The signal transmission layer 210 of the package substrate 200 may be connected to the first connection terminal 242, and may receive an electrical signal from an external configuration through the first connection terminal 242. In addition, the power transmission layer 220 of the package substrate 200 may be connected to the second connection terminal 244 and may receive power from an external configuration through the second connection terminal 244.

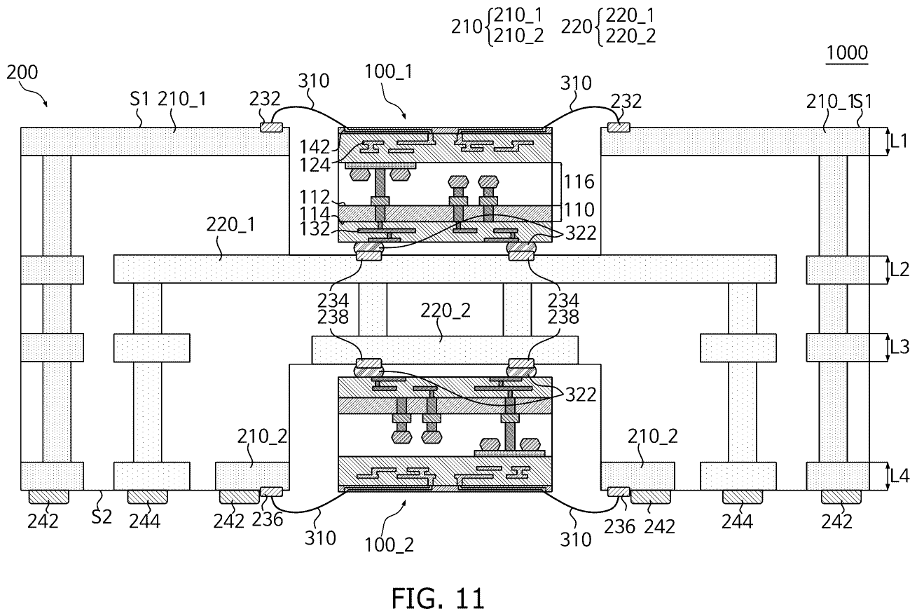

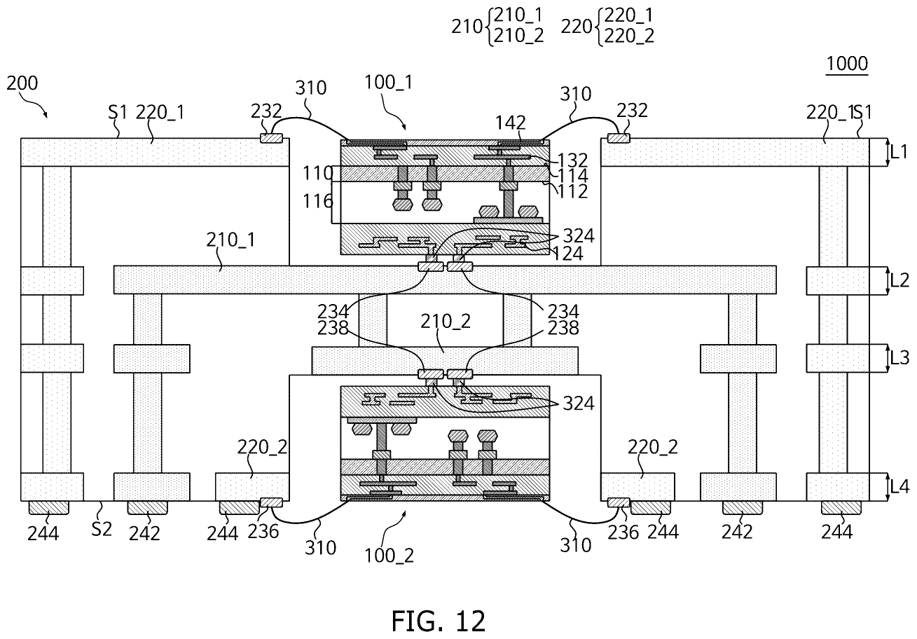

FIG. 11 is a cross-sectional view illustrating an example of the semiconductor package 1000 according to an aspect of the present disclosure, and FIG. 12 is a cross-sectional view illustrating an example of the semiconductor package 1000 according to another aspect of the present disclosure. The descriptions in conjunction with FIG. 11 or 12 may be applicable to the semiconductor packages in both figures, unless specified otherwise by the context and unless the descriptions explicitly conflict with what is depicted in each drawings.

Referring to FIG. 11, the semiconductor package 1000 may include the package substrate 200 (shown in FIG. 10) having cavities formed on both sides thereof, and a first semiconductor chip 100_1 and a second semiconductor chip 100_2 disposed on the package substrate 200.

Referring to FIG. 12, the semiconductor package 1000 may include a package substrate 200 (which is substantially the same as or similar to the package substrate 200 shown in FIG. 10) having the cavities formed on the both sides thereof, and a first semiconductor chip 100_1 and a second semiconductor chip 100_2 disposed on the package substrate 200.

For example, the first semiconductor chip 100_1 may be received in the first cavity formed on the first surface S1 of each of the package substrates 200, and the second semiconductor chip 100_2 may be received in the second cavity formed on the second surface S2 of each of the package substrates 200.

The first semiconductor chip 100_1 and the second semiconductor chip 100_2 received in the cavities may be the same type of semiconductor chip. The first semiconductor chip 100_1 and the second semiconductor chip 100_2 may have the same structure.

For example, as illustrated in FIG. 11, the first semiconductor chip 100_1 and the second semiconductor chip 100_2 may include the semiconductor substrate 110 including the first surface 112 (e.g., front surface) and the second surface 114 (e.g., rear surface) opposite to the first surface 112, the element region 116 and the signal wiring layer 124 disposed on the first surface 112 of the semiconductor substrate 110, the redistribution layer 142 disposed on the signal wiring layer 124, and the power wiring layer 132 disposed on the second surface 114 of the semiconductor substrate 110. The first semiconductor chip 100_1 and the second semiconductor chip 100_2 may each be disposed on the bottom surface of each of the first cavity and the second cavity such that the second surface 114 of the semiconductor substrate 110 faces the bottom surface of the cavity, as illustrated in FIG. 11.

As another example, as illustrated in FIG. 12, the first semiconductor chip 100_1 and the second semiconductor chip 100_2 may include the semiconductor substrate 110 including the first surface 112 (e.g., front surface) and the second surface 114 (e.g., rear surface) opposite to the first surface 112, the element region 116 and the signal wiring layer 124 disposed on the first surface 112 of the semiconductor substrate 110, the power wiring layer 132 disposed on the second surface 114 of the semiconductor substrate 110, and the redistribution layer 142 disposed on the power wiring layer 132. For example, the first semiconductor chip 100_1 and the second semiconductor chip 100_2 may each be disposed on the bottom surface of each of the first cavity and the second cavity in the form of a flip chip such that the first surface 112 of the semiconductor substrate 110 faces the bottom surface of the cavity, as illustrated in FIG. 12.

The semiconductor package 1000 may further include the bonding wire 310 and the bumps 322 and 324 to connect the semiconductor chip 100 and the semiconductor substrate 110. For example, as illustrated in FIGS. 11 and 12, the bonding wire 310 may connect the bonding pads 232 and 236 formed on the peripheral region of each cavity and the redistribution layer 142 of the semiconductor chip 100 received in each cavity, and the bumps 322 and 324 may connect the contact pads 234 and 238 formed on the bottom surface of each cavity and the power wiring layer 132 or the signal wiring layer 124 of the semiconductor chip 100 received in each cavity.

As described above, by mounting a plurality of semiconductor chips 100 in a plurality of cavities formed on both sides of the package substrate 200, it is possible to implement a high-capacity semiconductor package 1000 minimizing the package size.

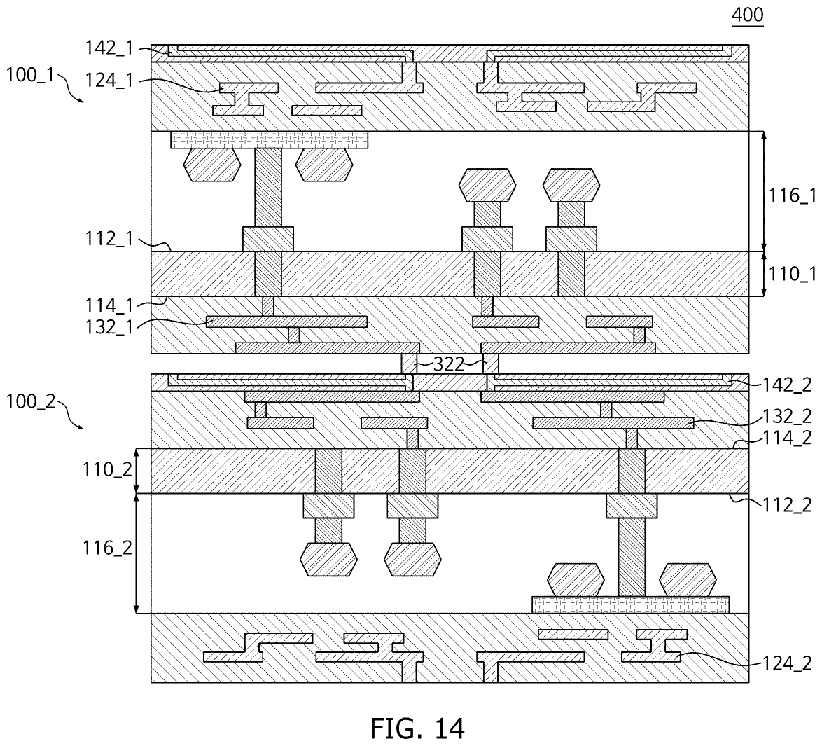

FIG. 13 is a cross-sectional view illustrating an example of a chip stack 400 according to an aspect of the present disclosure, and FIG. 14 is a cross-sectional view illustrating an example of the chip stack 400 according to another aspect of the present disclosure. The descriptions in conjunction with FIG. 13 or 14 may be applied to the semiconductor stack chips in both figures, unless specified otherwise by the context and unless the descriptions explicitly conflict with what is depicted in each drawings.

Referring to FIGS. 13 and 14, the chip stack 400 may include a first semiconductor chip 100_1, a second semiconductor chip 100_2, and bump 324 connecting the first semiconductor chip 100_1 and the second semiconductor chip 100_2. As shown in the drawings, each of the first semiconductor chip 100_1 and the second semiconductor chip 100_2 may have substantially the same structure as (or similar structure to) the structure of the semiconductor chip 100 shown in the FIG. 1 or 2.

The first semiconductor chip 100_1 may include a semiconductor substrate 110_1 including a first surface 112_1 and a second surface 114_1 opposite to the first surface 112_1, an element region 116_1 and a signal wiring layer 124_1 disposed on the first surface 112_1 of the semiconductor substrate 110_1, the first redistribution layer 142_1 disposed on the signal wiring layer 124_1, and a power wiring layer 132_1 disposed on the second surface 114_1 of the semiconductor substrate 110_1.

In addition, the second semiconductor chip 100_2 may include a semiconductor substrate 110_2 including a first surface 112_2 and a second surface 114_2 opposite to the first surface 112_2, an element region 116_2 and a signal wiring layer 124_2 disposed on the first surface 112_2 of the semiconductor substrate 110_2, a power wiring layer 132_2 disposed on the second surface 114_2 of the semiconductor substrate 110_2, and the second redistribution layer 142_2 disposed on the power wiring layer 132_2.

The chip stack 400 may refer to a stacked structure of the first semiconductor chip 100_1 and the second semiconductor chip 100_2. For example, the chip stack 400 may refer to a structure in which the second semiconductor chip 100_2 is stacked on the first semiconductor chip 100_1.

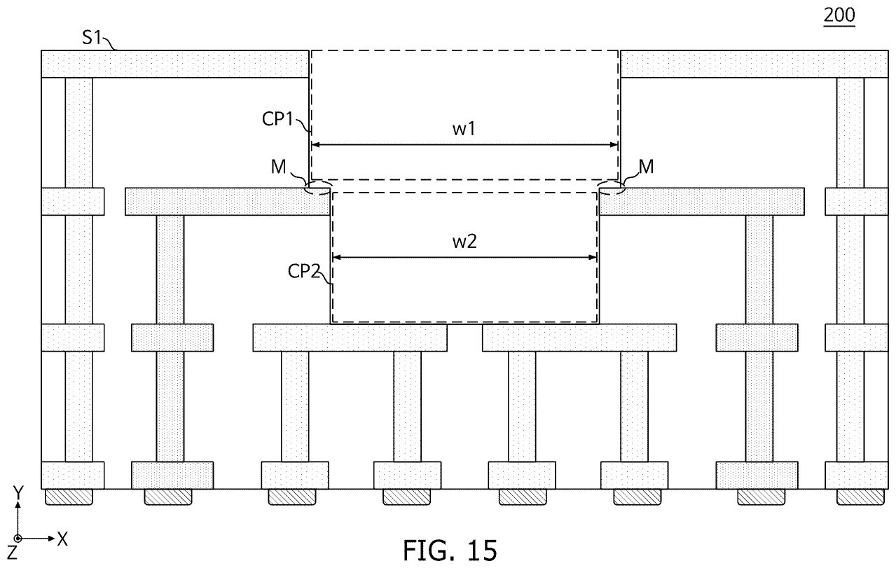

For example, as illustrated in FIG. 13, the second semiconductor chip 100_2 may be stacked on the first semiconductor chip 100_1 such that the signal wiring layer 124_2 of the second semiconductor chip 100_2 faces the first redistribution layer 142_1 of the first semiconductor chip 100_1. In this example, the first redistribution layer 142_1 of the first semiconductor chip 100_1 and the signal wiring layer 124_2 of the second semiconductor chip 100_2 may be connected through the bump 324. A pad for connection with the signal wiring layer 124_2 of the second semiconductor chip 100_2 may be formed on the first redistribution layer 142_1 of the first semiconductor chip 100_1. Additionally, a pad for connection with the bonding pad of the package substrate (shown in FIG. 15) may be formed on the first redistribution layer 142_1 of the first semiconductor chip 100_1. In addition, a pad for connection with the bonding pad of the package substrate (shown in FIG. 15) may be formed on the second redistribution layer 142_2 of the second semiconductor chip 100_2.

As another example, the chip stack 400 may refer to a semiconductor stack chip in which the first semiconductor chip 100_1 is stacked on the second semiconductor chip 100_2. For example, as illustrated in FIG. 14, the first semiconductor chip 100_1 may be stacked on the second semiconductor chip 100_2 such that the power wiring layer 132_1 of the first semiconductor chip 100_1 faces the second redistribution layer 142_2 of the second semiconductor chip 100_2. In this example, the power wiring layer 132_1 of the first semiconductor chip 100_1 and the second redistribution layer 142_2 of the second semiconductor chip 100_2 may be connected through the bump 322. A pad for connection with the power wiring layer 132_1 of the first semiconductor chip 100_1 may be formed on the second redistribution layer 142_2 of the second semiconductor chip 100_2. Additionally, a pad for connection with the bonding pad of the package substrate (shown in FIG. 15) may be further formed on the second redistribution layer 142_2 of the second semiconductor chip 100_2. In addition, a pad for connection with the bonding pad of the package substrate (shown in FIG. 15) may be formed on the first redistribution layer 142_1 of the first semiconductor chip 100_1.

FIG. 15 is a cross-sectional view illustrating an example of the package substrate 200 including a stepped cavity formed therein. The stepped cavity may be formed on the first surface S1 of the package substrate 200. The stepped cavity may include a first cavity portion CP1 having a first width W1 and a second cavity portion CP2 having a second width W2. The first and second cavity portions CP1 and CP2 may be formed in order from the first surface S1 of the package substrate 200 (in order from top, or in order from the outside of the package substrate). The first cavity portion CP1 may be disposed closer to the first surface S1 of the package substrate 200 than the second cavity portion CP2. The second width W2 of the second cavity portion CP2 may be less than the first width W1 of the first cavity portion CP1, and an intermediate bottom surface M may be formed in a portion of the package substrate 200 at which the first cavity portion CP1 and the second cavity portion CP2 are connected to each other. The widths W1 and W2 are dimensions measured in the horizontal direction (direction X).

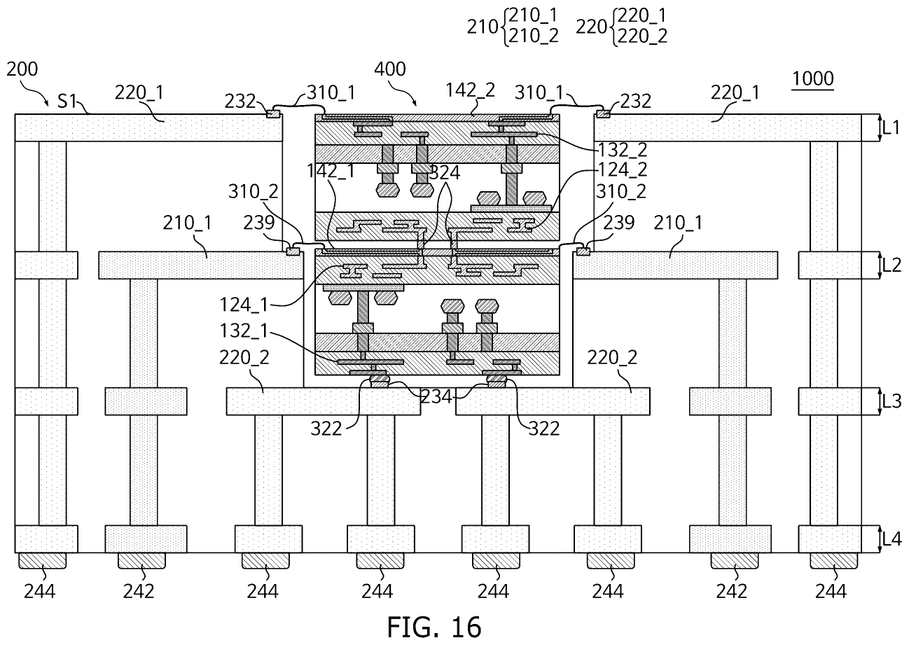

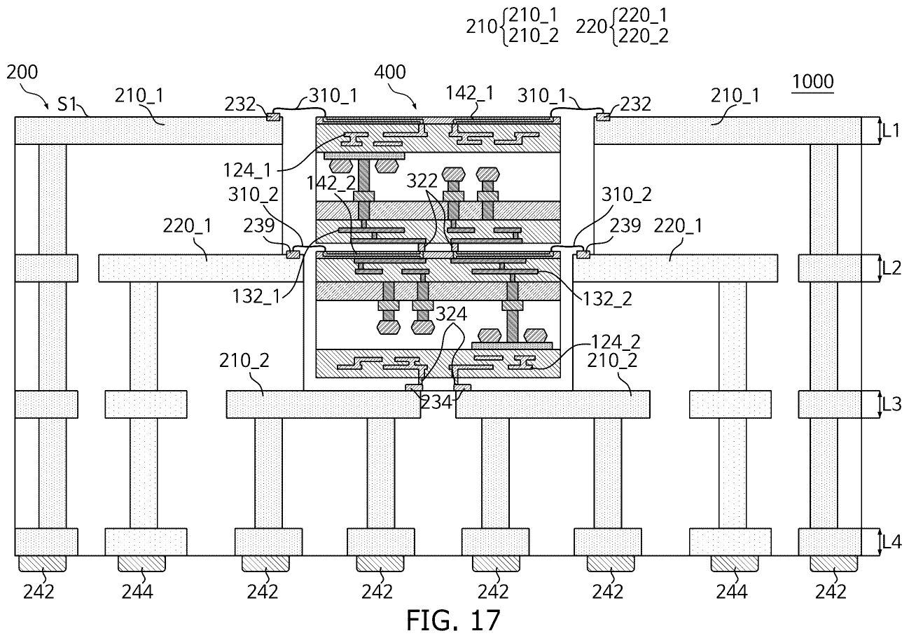

At least a portion of the chip stack 400 may be received in the stepped cavity. This will be described below in more detail with reference to FIGS. 16 and 17.

FIG. 16 is a cross-sectional view illustrating an example of the semiconductor package 1000 including the chip stack 400 (shown in FIG. 13 or 14) according to an aspect of the present disclosure, and FIG. 17 is a cross-sectional view illustrating an example of the semiconductor package 1000 including the chip stack 400 according to another aspect of the present disclosure. The descriptions in conjunction with FIG. 16 or 17 may be applicable to the semiconductor packages in both figures, unless specified otherwise by the context and unless the descriptions explicitly conflict with what is depicted in each drawings.

The semiconductor package 1000 may include the package substrate 200 (shown in FIG. 15) including the stepped cavity formed in the first surface S1 and the chip stack 400 received in the cavity of the package substrate 200.

The first bonding pad 232 may be formed on a peripheral region of the cavity of the first surface S1 of the package substrate 200. In addition, a second bonding pad 239 may be formed on an intermediate bottom surface (as indicated by M in FIG. 15) formed by the stepped portion (a difference in width between the two cavity portions) of the cavity. The intermediate bottom surface may be formed on the step-shaped sidewall of the cavity. In addition, the contact pad 234 may be formed on the bottom surface of the cavity. The intermediate bottom surface M may be described as a horizontal step surface. The horizontal step surface may be a horizontal surface portion of the step-shaped sidewall.

Referring to FIG. 16, the first bonding pad 232 and the contact pad 234 may be connected to the power transmission layer 220 of the package substrate 200, and the second bonding pad 239 may be connected to the signal transmission layer 210 of the package substrate 200. For example, the first bonding pad 232 may be connected to the first power transmission layer 220_1. The first power transmission layer 220_1 may be a part of the first wiring layer L1 of the package substrate 200. The second bonding pad 239 may be connected to the first signal transmission layer 210_1. The first signal transmission layer 210_1 may be a part of the second wiring layer L2 of the package substrate 200. The contact pad 234 may be connected to the second power transmission layer 220_2. The second power transmission layer 220_2 may be a part of the third wiring layer L3 of the package substrate 200. The signal transmission layer 210_1 may be positioned between the two power transmission layers 220_1 and 220_2 such that the signal transmission layer 210_1 has a structure of a strip line, thereby preventing cross-talk. As a result, the signal integrity can be improved.

The chip stack 400 (illustrated in FIG. 13) may be disposed on the package substrate 200. In the chip stack 400, the signal wiring portions of the two semiconductor chips are stacked to face each other may be disposed on the package substrate 200. Specifically, as illustrated in FIG. 13. The signal wiring portions of the two semiconductor chips are electrically connected and face each other as illustrated in FIG. 13. For example, the chip stack 400, in which the second semiconductor chip 100_2 is stacked on the first semiconductor chip 100_1, may be received in the cavity of the package substrate 200 such that the signal wiring layer 124_2 of the second semiconductor chip 100_2 faces the first redistribution layer 142_1 disposed on the signal wiring layer 124_1 of the first semiconductor chip 100_1. For example, the second redistribution layer 142_2 disposed on the power wiring layer 132_2 of the second semiconductor chip 100_2 may be connected to the first bonding pad 232 through a first bonding wire 310_1. In addition, the first redistribution layer 142_1 disposed on the signal wiring layer 124_1 of the first semiconductor chip 100_1 may be connected to the second bonding pad 239, and the power wiring layer 132_1 of the first semiconductor chip 100_1 may be connected to the contact pad 234 through the bump 322.

For example, a signal received through the first connection terminal 242 of the package substrate 200 may be transmitted to the first redistribution layer 142_1 of the first semiconductor chip 100_1 through the signal transmission layer 210 and a second bonding wire 310_2. In addition, the signal transmitted to the first redistribution layer 142_1 may be transmitted to the signal wiring layer 124_1 of the first semiconductor chip 100_1 and the signal wiring layer 124_2 of the second semiconductor chip 100_2. The signals may diverge in the first redistribution layer 142_1 of the chip stack 400, and the diverged signals may be transmitted to the two semiconductor chips included in the chip stack 400. Accordingly, because the signals transmitted to the two semiconductor chips included in the chip stack 400 diverge in the first redistribution layer 142_1 of the chip stack 400, most of the signal transmission paths coincide and thus the signal transmission speed may be similar. For example, the signal transmission paths may be configured to have the same signal transmission length. The signal transmission length may be a length from an external configuration such as a CPU to a corresponding one of the two semiconductor chips, and thus the signal transmission speed may be enhanced

In addition, the power supply path to the first semiconductor chip 100_1 may be configured separately from the power supply path to the second semiconductor chip 100_2. For example, the power supplied through the second connection terminal 244 of the package substrate 200 may be supplied to the first semiconductor chip 100_1 through the power transmission layer 220 and the bump 322. In addition, the power supplied through the second connection terminal 244 of the package substrate 200 may be supplied to the second semiconductor chip 100_2 through the power transmission layer 220, the first bonding wire 310_1, and the second redistribution layer 142_2.

Referring to FIG. 17, the first bonding pad 232 and the contact pad 234 may be connected to the signal transmission layer 210 of the package substrate 200, and the second bonding pad 239 may be connected to the power transmission layer 220 of the package substrate 200. For example, the first bonding pad 232 may be connected to the first signal transmission layer 210_1. The first signal transmission layer 210_1 may be a part of the first wiring layer L1 of the package substrate 200. The second bonding pad 239 may be connected to the first power transmission layer 220_1. The first power transmission layer 220_1 may be a part of the second wiring layer L2 of the package substrate 200. The contact pad 234 may be connected to the second signal transmission layer 210_2. The second signal transmission layer 210_2 may be a part of the third wiring layer L3 of the package substrate 200. For example, the first power transmission layer 220_1 is positioned between the two signal transmission layers 210_1 and 210_2, and because the first power transmission layer 220_1 has a structure of a strip line, the power integrity can be improved.

The chip stack 400 (illustrated in FIG. 14) may be disposed on the package substrate 200. In the chip stack 400, the power wiring portions of the two semiconductor chips are stacked to face each other may be disposed on the package substrate 200. Specifically. The power wiring portions of the two semiconductor chips are electrically connected and face each other as illustrated in FIG. 14. For example, as illustrated in FIG. 17, the chip stack 400 in which the first semiconductor chip 100_1 is stacked on the second semiconductor chip 100_2 may be received in the cavity of the package substrate 200 such that the power wiring layer 132_1 of the first semiconductor chip 100_1 faces the second redistribution layer 142_2 disposed on the power wiring layer 132_2 of the second semiconductor chip 100_2. For example, the first redistribution layer 142_1 disposed on the signal wiring layer 124_1 of the first semiconductor chip 100_1 may be connected to the first bonding pad 232 through the first bonding wire 310_1. In addition, the second redistribution layer 142_2 disposed on the power wiring layer 132_2 of the second semiconductor chip 100_2 may be connected to the second bonding pad 239, and the signal wiring layer 124_2 of the second semiconductor chip 100_2 may be connected to the contact pad 234 through the bump 324.

For example, a signal received through the first connection terminal 242 of the package substrate 200 may be supplied to the second semiconductor chip 100_2 through the signal transmission layer 210 and the bump 324. In addition, the signal received through the first connection terminal 242 of the package substrate 200 may be supplied to the first semiconductor chip 100_1 through the signal transmission layer 210, the first bonding wire 310_1, and the first redistribution layer 142_1.

In addition, the power supplied through the second connection terminal 244 of the package substrate 200 may be transmitted to the second redistribution layer 142_2 of the second semiconductor chip 100_2 through the power transmission layer 220 and the second bonding wire 310_2. In addition, the signal transmitted to the second redistribution layer 142_2 may be transmitted to the power wiring layer 132_1 of the first semiconductor chip 100_1 and the power wiring layer 132_2 of the second semiconductor chip 100_2.

Certain examples of the present disclosure have been described above for purposes of illustration only, and those skilled in the art with ordinary knowledge of the present invention will be able to make various modifications, changes and additions within the spirit and scope of the present invention, and such modifications, changes and additions should be construed to be included in a scope of the invention and the claims.

It should be understood that those of ordinary skill in the art to which the present disclosure pertains can make various substitutions, modifications and changes without departing from the technical spirit of the present disclosure, and thus, the present invention is not limited by the embodiments described above and the accompanying drawings.

What is claimed is:

1. A semiconductor package comprising:
a package substrate; and
a first semiconductor chip disposed on the package substrate, wherein the first semiconductor chip includes:
a semiconductor substrate including a first surface and a second surface opposite to the first surface;
a circuit pattern region disposed on the first surface of the semiconductor substrate and including a plurality of circuit patterns;
a signal wiring layer disposed on the circuit pattern region and electrically connected to the plurality of circuit patterns; and
a power wiring layer disposed on the second surface of the semiconductor substrate and electrically connected to the plurality of circuit patterns by a plurality of through vias extending through the semiconductor substrate,
wherein the package substrate includes:
a signal transmission pattern electrically connected to the signal wiring layer of the first semiconductor chip; and
a power transmission pattern electrically connected to the power wiring layer of the first semiconductor chip.

2. The semiconductor package according to claim 1, further comprising a bonding wire and a bump,
wherein the first semiconductor chip is disposed on a first surface of the package substrate such that the second surface of the semiconductor substrate faces the first surface of the package substrate, and the first semiconductor chip further includes a redistribution layer disposed on the signal wiring layer and electrically connected to the signal wiring layer,
wherein the package substrate further includes:
a contact pad formed on a chip placement region of the first surface of the package substrate and electrically connected to the power transmission pattern; and
a bonding pad formed on a chip peripheral region and on the first surface of the package substrate, the bonding pad electrically connected to the signal transmission pattern, and
wherein the bonding wire is electrically connected to the redistribution layer of the first semiconductor chip and to the bonding pad, and wherein the bump is electrically connected to the power wiring layer of the first semiconductor chip and to the contact pad.

3. The semiconductor package according to claim 1, further comprising a bonding wire and a bump,
wherein the first semiconductor chip is disposed on a first surface of the package substrate such that the first surface of the semiconductor substrate faces the first surface of the package substrate, and the first semiconductor chip further includes a redistribution layer disposed on the power wiring layer and electrically connected to the power wiring layer,
wherein the package substrate further includes:
a contact pad formed on a chip placement region of the first surface of the package substrate and electrically connected to the signal transmission pattern; and
a bonding pad formed on a chip peripheral region and on the first surface of the package substrate, the bonding pad electrically connected to the power transmission pattern, and
wherein the bonding wire is electrically connected to the redistribution layer of the first semiconductor chip and the bonding pad, and the bump is electrically connected to the signal wiring layer of the first semiconductor chip and the contact pad.

4. The semiconductor package according to claim 1, further comprising a first contact pad and a first bonding pad,
wherein a first cavity is formed on a first surface of the package substrate, at least a portion of the first semiconductor chip is accommodated in the first cavity, and the first contact pad is formed on a bottom surface of the first cavity, and
wherein the first bonding pad formed on a peripheral region of the first cavity and on the first surface of the package substrate.

5. The semiconductor package according to claim 4, further comprising a bonding wire and a bump,
wherein the first semiconductor chip is disposed such that the second surface of the semiconductor substrate faces the bottom surface of the first cavity,
wherein the first semiconductor chip further includes a redistribution layer disposed on the signal wiring layer and electrically connected to the signal wiring layer, and
wherein the first contact pad is electrically connected to the power transmission pattern, and
the first bonding pad is electrically connected to the signal transmission pattern, and the bonding wire electrically connects the redistribution layer of the first semiconductor chip and the first bonding pad, and the bump electrically connects the power wiring layer of the first semiconductor chip and the first contact pad.

6. The semiconductor package according to claim 4, further comprising a bonding wire and a bump,
wherein the first semiconductor chip is disposed such that the first surface of the semiconductor substrate faces the bottom surface of the first cavity,
wherein the first semiconductor chip further includes a redistribution layer disposed on the power wiring layer and electrically connected to the power wiring layer, and
wherein the first contact pad is electrically connected to the signal transmission pattern, the first bonding pad is electrically connected to the power transmission pattern, the bonding wire electrically connects the redistribution layer of the first semiconductor chip and the first bonding pad, and the bump electrically connects the signal wiring layer of the first semiconductor chip and the first contact pad.

7. The semiconductor package according to claim 4, wherein a distance from the bottom surface of the first cavity to an upper surface of the first semiconductor chip is the same as a depth of the first cavity.

8. The semiconductor package according to claim 4, wherein a difference between a depth of the first cavity and a distance from the bottom surface of the first cavity to an upper surface of the first semiconductor chip is less than the distance from the bottom surface of the first cavity to the upper surface of the first semiconductor chip.

9. The semiconductor package according to claim 4, wherein the signal transmission pattern and the power transmission pattern are parts of a plurality of wiring layers of the package substrate,
the plurality of wiring layers are stacked in a vertical direction perpendicular to the first and second surfaces of the package substrate,
each of the plurality of wiring layers includes a first wiring layer including a wiring pattern directly connected to the first bonding pad and a second wiring layer including a wiring pattern directly connected to the first contact pad, and
a distance between the first wiring layer and the second wiring layer is the same as a thickness of the first semiconductor chip.

10. The semiconductor package according to claim 4, further comprising a second semiconductor chip,
wherein the package substrate further includes:
a second cavity provided on the second surface of the package substrate;
a second contact pad formed on a bottom surface of the second cavity; and
a second bonding pad formed on a peripheral region of the second cavity of the second surface of the package substrate, and
wherein at least a portion of the second semiconductor chip is accommodated in the second cavity.

11. The semiconductor package according to claim 10, wherein the first contact pad and the second contact pad are electrically connected to the power transmission pattern, and
the first bonding pad and the second bonding pad are electrically connected to the signal transmission pattern.

12. The semiconductor package according to claim 10, wherein the first contact pad and the second contact pad are electrically connected to the signal transmission pattern, and
the first bonding pad and the second bonding pad are electrically connected to the power transmission pattern.

13. A semiconductor package, comprising:
a package substrate; and
a chip stack disposed on the package substrate and including a plurality of semiconductor chips including a first semiconductor chip and a second semiconductor chip stacked on each other,
wherein each of the first semiconductor chip and the second semiconductor chip includes:
a semiconductor substrate including a first surface and a second surface opposite to the first surface;
a circuit pattern region disposed on the first surface of the semiconductor substrate and including a plurality of circuit patterns;
a signal wiring layer disposed on the circuit pattern region and electrically connected to the plurality of circuit patterns; and
a power wiring layer disposed on the second surface of the semiconductor substrate and electrically connected to the plurality of circuit patterns by a plurality of through vias extending through the semiconductor substrate, and
wherein the package substrate includes:
a signal transmission pattern electrically connected to the signal wiring layer included in at least one of the first semiconductor chip and the second semiconductor chip; and
a power transmission pattern electrically connected to the power wiring layers of the first and second semiconductor chips included in at least one of the first semiconductor chip and the second semiconductor chip.

14. The semiconductor package according to claim 13, wherein the plurality of semiconductor chips are stacked such that the signal wiring layers of the first and second semiconductor chips face each other, or such that the power wiring layers of the first and second semiconductor chips face each other.

15. The semiconductor package according to claim 13,
wherein a cavity is formed on a first surface of the package substrate, and at least a portion of the chip stack is accommodated in the cavity,
wherein the cavity includes a first cavity portion having a first width and a second cavity portion having a second width less than the first width, and
wherein the package substrate further includes:
a first bonding pad formed on a peripheral region of the cavity and on the first surface of the package substrate;
a second bonding pad formed on a horizontal step surface of a step-shaped sidewall of the cavity; and
a contact pad formed on a bottom surface of the cavity.

16. The semiconductor package according to claim 15,
wherein the package substrate includes a plurality of wiring layers stacked in a vertical direction perpendicular to the first and second surfaces of the package substrate, and the plurality of wiring layers includes a second wiring layer positioned between a first wiring layer and a third wiring layer,
wherein the power transmission pattern is one of a plurality of power transmission patterns including first and second power transmission patterns, the first power transmission pattern is a part of the first wiring layer, the signal transmission pattern is a part of the second wiring layer, and the second power transmission pattern is a part of the third wiring layer, and
wherein the first bonding pad is electrically connected to the first power transmission pattern, the second bonding pad is electrically connected to the signal transmission pattern, and the contact pad is electrically connected to the second power transmission pattern.

17. The semiconductor package according to claim 16, further comprising a first bonding wire, a second bonding wire and a second bump,
wherein the first semiconductor chip further includes a first redistribution layer disposed on the signal wiring layer of the first semiconductor chip and electrically connected to the signal wiring layer of the first semiconductor chip,
wherein the second semiconductor chip further includes a second redistribution layer disposed on the power wiring layer of the second semiconductor chip and electrically connected to the power wiring layer of the second semiconductor chip,
wherein the second semiconductor chip is stacked on the first semiconductor chip such that the signal wiring layer of the second semiconductor chip faces the first redistribution layer of the first semiconductor chip,
wherein the chip stack further includes a first bump electrically connecting the first redistribution layer of the first semiconductor chip and the signal wiring layer of the second semiconductor chip, and
wherein the first bonding wire electrically connects the second redistribution layer of the second semiconductor chip and the first bonding pad, the second bonding wire electrically connects the first redistribution layer of the first semiconductor chip and the second bonding pad, and the second bump electrically connects the power wiring layer of the first semiconductor chip and the contact pad.

18. The semiconductor package according to claim 15,
wherein the package substrate includes a plurality of wiring layers stacked in a vertical direction perpendicular to the first and second surfaces of the package substrate, and the plurality of wiring layers includes a second wiring layer is positioned between a first wiring layer and a third wiring layer,
wherein the signal transmission pattern is one of a plurality of signal transmission patterns including first and second signal transmission patterns, the first signal transmission pattern is a part of the first wiring layer, the power transmission pattern is a part of the second wiring layer, and the second signal transmission pattern is a part of the third wiring layer, and
wherein the first bonding pad is electrically connected to the first signal transmission pattern, the second bonding pad is electrically connected to the power transmission pattern, and the contact pad is electrically connected to the second signal transmission pattern.

19. The semiconductor package according to claim 18, further comprising a first bonding wire, a second bonding wire and a second bump,
wherein the first semiconductor chip further includes a first redistribution layer disposed on the signal wiring layer of the first semiconductor chip and electrically connected to the signal wiring layer of the first semiconductor chip,
wherein the second semiconductor chip further includes a second redistribution layer disposed on the power wiring layer of the second semiconductor chip and electrically connected to the power wiring layer of the second semiconductor chip,
wherein the first semiconductor chip is stacked on the second semiconductor chip such that the power wiring layer of the first semiconductor chip faces the second redistribution layer of the second semiconductor chip,
wherein the chip stack further includes a first bump electrically connecting the second redistribution layer of the second semiconductor chip and the power wiring layer of the first semiconductor chip, and
wherein the first bonding wire electrically connects the first redistribution layer of the first semiconductor chip and the first bonding pad, the second bonding wire electrically connects the second redistribution layer of the second semiconductor chip and the second bonding pad, and the second bump electrically connects the signal wiring layer of the second semiconductor chip and the contact pad.

20. A semiconductor package, comprising:
a package substrate including a signal transmission pattern and a power transmission pattern; and
a semiconductor chip disposed on the package substrate, wherein the semiconductor chip includes:
a semiconductor substrate including a first surface and a second surface opposite to the first surface;
a circuit pattern region disposed on the first surface of the semiconductor substrate and including at least one circuit pattern;
a signal wiring portion including a signal wiring layer disposed on the circuit pattern region and electrically connected to the circuit pattern; and
a power wiring portion including a power wiring layer disposed on the second surface of the semiconductor substrate and electrically connected to the circuit pattern region by a through via extending through the semiconductor substrate,
wherein:
the signal wiring layer of the semiconductor chip is electrically connected to the signal transmission pattern of the package substrate, and
the power wiring layer of the semiconductor chip is electrically connected to the power transmission pattern of the package substrate.
